(19) United States
(12) Patent Application Publication
(10) Pub. No.: US 2009/0108311 A1
(43) Pub. Date: Apr. 30, 2009

(54) CMOS Detector with Reduced Sensitivity to X-Rays

(76) Inventor: Xinqiao Liu, Mountain View, CA (US)

Correspondence Address: THE LAW OFFICES OF CALVIN B. WARD, 18 CROW CANYON COURT, SUITE 305, SAN RAMON, CA, 94583, US

(21) Appl. No.: 11/924,522

(22) Filed: Oct. 25, 2007

(51) Int. Cl. H01L 31/062; H01L 25/00

(52) U.S. Cl. 257/294; 250/370.09; 257/E31.122

(57) ABSTRACT

An imaging array and method for operating the same is disclosed. The imaging array includes a semiconductor substrate having an epitaxial layer of semiconductor material deposited on a first surface thereof. A plurality of photodiodes is formed in a top surface of the epitaxial layer. The imaging array also includes a depletion layer underlying the photodiodes and disposed between the epitaxial layer and the semiconductor substrate. The depletion layer is connected to a power rail for removing electrons collected in the depletion layer. The depletion layer collects electrons generated by x-ray interactions in the substrate. The depletion layer can also be biased such that the depletion layer collects electrons collected by the photodiodes to provide a reset operation for the imaging array. The current flowing through the depletion layer can be used to generate a trigger signal indicating the start of an x-ray exposure.

### BACKGROUND OF THE INVENTION

Dental x-rays are typically taken with a film that is placed in the patient's mouth. The film is exposed through the teeth by an x-ray source that resides outside the patient's head. While this method has been in use for many years, it has its disadvantages. First, the patient is exposed to a significant dose of x-rays. This dose is accumulative over the patient's lifetime. Second, the time, cost, and equipment needed to process the film increases the cost of the dental examination. Third, the chemicals utilized in processing the film pose a disposal problem.

These problems have led to several attempts to replace the film component of the traditional x-ray examination with a solid-state sensor that is placed in the patient's mouth to record the x-ray image. In such systems, a layer of scintillation material is used to convert the x-rays to visible light. The visible light is then imaged onto a solid-state imaging array. Since solid-state x-ray sensors of this type are significantly more sensitive to x-rays than the films utilized today, the x-ray dosage can be reduced, typically, by a factor of 10. In addition, the sensor is re-used, and hence, the cost and disposal problems associated with the conventional x-ray system are avoided. Finally, since the image is in digital form, systems based on solid-state sensors are easily adapted to paperless office systems.

Unfortunately, these sensors are much thicker than the conventional film based sensors and the resolution of the sensors is also less than that of conventional film-based sensors. The sensors include a channel plate between the scintillation material and the image-recording element, which is typically a silicon-based imaging array. When an x-ray is converted in a pixel of the imaging array, the resultant signal can be much greater than the signal produced by the light from the scintillator. The probability of such a conversion event is small, and hence, the x-ray hits result in scattered bright pixels in the image that render the image objectionable. To reduce these events, a layer of shielding material that transmits the light from the scintillator to the imaging array is used. The shielding layer typically consists of a bundle of optical fibers that images the surface of the scintillator onto the surface of the imaging array. The optical fibers are doped with a heavy metal that absorbs x-rays that are not converted in the scintillation material. The shielding layer blocks most of the x-rays from reaching the image sensor, and hence, reduces the number of bright pixels to an acceptable level.

While the shielding layer solves the bright pixel problem, it introduces new problems. The shielding plate is typically greater than 2.5 mm in thickness, and hence, significantly increases the thickness of the apparatus that is placed in the patient's mouth. The increased thickness is objectionable to many patients. In addition, the cost of the shielding plate is a significant fraction of the cost of the dental sensor.

In addition to requiring shielding from x-rays that enter the sensor from the front surface of the sensor, shielding is also required on the backside of the sensor. The x-ray sources used in dentistry generate a widely diverging x-ray pattern. A significant fraction of the x-rays strike the patient at locations other than those being imaged by the sensor. For example, x-rays can pass through the portion of the jaw above and below the area being imaged. These x-rays scatter off of other tissue in the patient's head such as the scull and jawbone. The scattered x-rays can enter the sensor through the backside of the sensor which is not protected by the shielding layer. To prevent these x-rays from converting in the silicon detector, additional shielding layers, typically lead, are required behind the sensor and on the sides of the sensor. This layer of lead further increases the system thickness, and also poses both health and environmental concerns if the plastic housing becomes defective.

Unlike film-based sensors, solid-state sensors must utilize some form of exposure control. In conventional film-based dental x-ray systems, the exposure is controlled by the x-ray tube being turned on and off. Since the film does not record an image when the x-ray source is off, no additional exposure control is required. Solid-state image sensors suffer from dark current. That is, even in the absence of light, the photodiodes accumulate some charge. Hence, in solid state imaging systems, the photodiode array is reset just before the start of the image exposure. Unfortunately, conventional dental x-ray systems do not provide a convenient reset signal that can be used to reset the image sensor just before the x-ray tube is turned on. If the sensor is reset prior to the placement of the sensor in the patient's mouth, the time period between the reset and the exposure is too long, and the image suffers from a dark current background. Hence, solid-state imaging systems that are to replace conventional film in dental applications must provide some form of automatic reset in which the x-ray pulse is detected so that the image sensor is reset at the beginning of the exposure.

A number of systems have been proposed to deal with the synchronization of the imaging sensor with the x-ray pulse. The most straight forward approach would be to provide a synchronization signal similar to the pushbutton on a conventional camera. The imaging array could then be reset and the x-ray source triggered in the proper time sequence to minimize the exposure to the patient. Unfortunately, this strategy requires that the existing millions of x-ray machines already in place in dental facilities be modified at a considerable cost. Hence, some other form of triggering system has been sought.

In one class of triggering system, a separate set of detectors is used to detect the beginning of the x-ray exposure and trigger the reset, image acquisition, and readout when x-rays are detected. These additional detectors typically include additional photodiodes that are placed around the image sensor and are monitored to determine the start of the exposure. This type of system has three problems. First, the area of the separate sensors is relatively small, and hence, the sensitivity of the detection is less than ideal. In essence, the exposure sensors are equivalent to a few extra pixels in the image plane. The position of these sensors is behind the teeth or jaw bone, and hence, the time needed to provide a sufficient signal is of the order of the time needed to provide an image. Accordingly, the exposure of the patient to the x-rays is increased. Second, the sensors do not sample the entire image, and hence, the triggering decision is made on data that is not necessarily representative of the image. Finally, the sensors are often separate from the array, and hence, the cost of the imaging system is increased.

In another class of prior art system, the imaging array is continually cycled. During each cycle, the imaging array is reset, allowed to accumulate charge for a predetermined period of time and then readout. If the image that is readout indicates the accumulation of a significant charge above that expected from the dark current, the system assumes that the exposure has begun, and the array is reset and allowed to accumulate the final image. This system has a better signal-to-noise ratio than systems based on a few small sensors, since the charge from a more representative set of photodiodes in the actual image is added together to make the triggering decision. Unfortunately, this system consumes a significant amount of power due to the repeated readout cycles, which is of concern in systems that utilize battery power to power the sensor. In addition, the detection time is increased by the time needed to readout each image during the detection phase.

### SUMMARY OF THE INVENTION

The present invention includes an imaging array and method for operating the same to reduce background caused by x-ray exposure of the imaging array. The imaging array includes a semiconductor substrate having an epitaxial layer of semiconductor material deposited on a first surface thereof. A plurality of photodiodes is formed in a top surface of the epitaxial layer. The imaging array also includes a depletion layer underlying the photodiodes and disposed between the epitaxial layer and the semiconductor substrate. The depletion layer is connected to a power rail for removing electrons collected in the depletion layer. The depletion layer collects electrons generated by x-ray interactions in the substrate. The depletion layer can further be biased such that the depletion layer collects electrons collected by the photodiodes to provide a reset operation for the imaging array. The current flowing through the depletion layer can be used to generate a trigger signal indicating the start of an x-ray exposure.

### BRIEF DESCRIPTION OF THE DRAWINGS

FIG. 1 is a top view of a dental sensor 30.

FIG. 2 is a cross-sectional view through line 2-2 shown in FIG. 1.

FIG. 3 is a schematic drawing of a prior art CMOS imaging array of the type normally used with dental sensor 30.

FIG. 4 is a schematic drawing of a prior art pixel sensor that is commonly used in CMOS imaging arrays.

FIG. 5 is a cross-sectional view of a section of a prior art imaging array.

FIG. 6 is a cross-sectional view of a portion of an image sensor according to one embodiment of the present invention.

FIG. 7 is a cross-sectional view of another embodiment of an imaging array according to the present invention.

### DETAILED DESCRIPTION OF THE PREFERRED EMBODIMENTS OF THE INVENTION

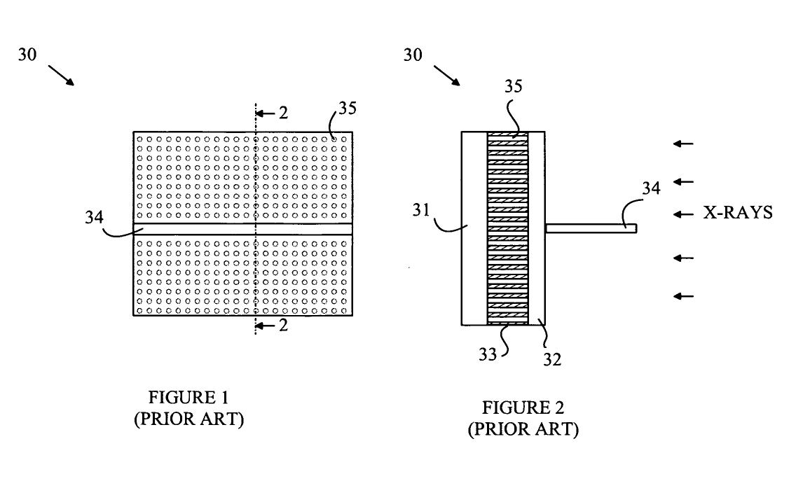

The manner in which the present invention provides its advantages can be more easily understood with reference to FIGS. 1 and 2, which illustrate a prior art dental sensor. FIG. 1 is a top view of dental sensor 30, and FIG. 2 is a cross-sectional view through line 2-2 shown in FIG. 1. Dental sensor 30 includes a layer 32 of scintillation material that converts x-rays to light in the visible region of the spectrum. The light generated in layer 32 is viewed by an image sensor 31 through a channel plate 33 that consists of a bundle of optical fibers that map the surface of the scintillation material onto image sensor 31. Sensor 30 is placed inside the patient's mouth and held in place by the patient biting down on tab 34. When x-rays from a source outside the mouth impinge on sensor 30 after passing through the patient's teeth, the x-rays strike layer 32. Each interaction between an X-ray and the material of layer 32 results in multiple visible photons being generated. The photons are emitted in all directions. Channel plate 33 blocks photons that are traveling in directions other than that defined by the aperture of the optical fibers shown at 35. Channel plate 33 is made primarily of glass fibers. The metal doped glass absorbs x-rays that escape from the scintillation layer without being converted. The thickness of the glass is chosen such that the number of x-rays that reach sensor 31 is reduced to the point that interactions between the x-rays and the pixels in sensor 31 are rare.

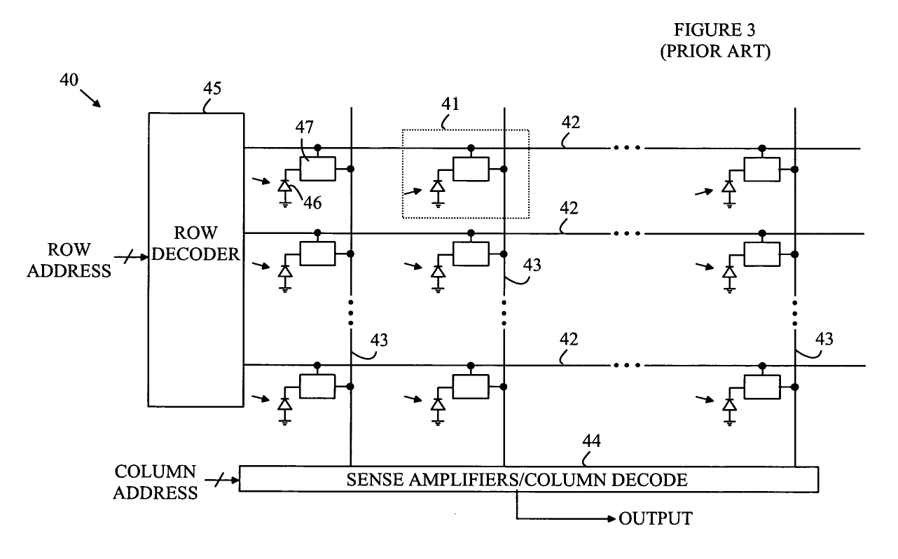

Refer now to FIG. 3, which is a schematic drawing of a prior art CMOS imaging array of the type normally used with dental sensor 30. Imaging array 40 is constructed from a rectangular array of pixel sensors 41. Each pixel sensor includes a photodiode 46 and an interface circuit 47. The details of the interface circuit depend on the particular pixel design. However, all of the pixel sensors include a gate that is connected to a row line 42 that is used to connect that pixel sensor to a bit line 43. The specific row that is enabled at any time is determined by a row address that is input to a row decoder 45. The row select lines are a parallel array of conductors that run horizontally in the metal layers over the substrate in which the photodiodes and interface circuitry are constructed.

The various bit lines terminate in a column processing circuit 44 that typically includes sense amplifiers and column decoders. The bit lines are a parallel array of conductors that run vertically in the metal layers over the substrate in which the photodiode and interface circuitry are constructed. Each sense amplifier reads the signal produced by the pixel that is currently connected to the bit line processed by that sense amplifier. The sense amplifiers may generate a digital output signal by utilizing an analog-to-digital converter (ADC). At any given time, a single pixel sensor is readout from the imaging array. The specific column that is readout is determined by a column address that is utilized by a column decoder to connect the sense amplifier/ADC output from that column to circuitry that is external to the imaging array.

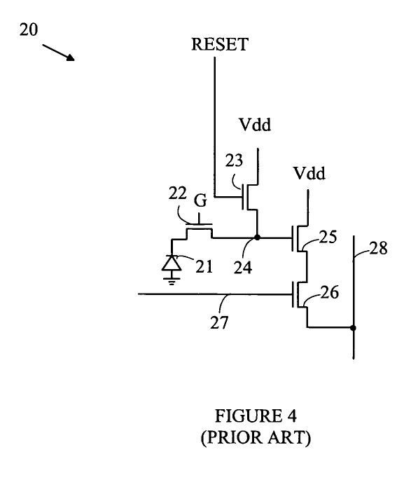

Refer now to FIG. 4, which is a schematic drawing of a prior art pixel sensor that is commonly used in CMOS imaging arrays. Pixel sensor 20 includes 4 transistors and is often referred to as a 4T pixel cell. Photodiode 21 is reset prior to the image exposure by placing gates 22 and 23 in the conductive state, such that the cathode of photodiode 21 is connected to V_{dd}. After the reset operation, gates 22 and 23 are placed in the non-conductive state. During the image exposure, a charge that is related to the light exposure is stored adjacent to gate 22 in photodiode 21. During readout, charge from photodiode 21 is transferred onto node 24 by transistor 22 and converted to a voltage by transistor 25. When pixel sensor 20 is selected by a signal on row line 27, transistor 26 applies this voltage to bit line 28.

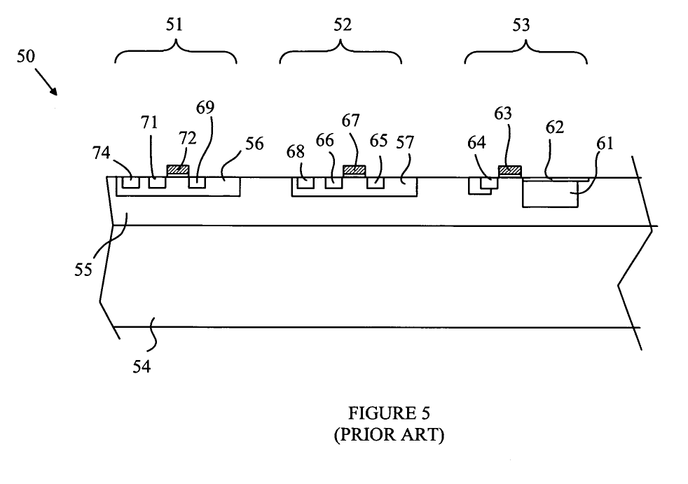

Refer now to FIG. 5, which is a cross-sectional view of a section of a prior art imaging array. Imaging array 50 is constructed on a P+ substrate 54 by growing a P− epi layer 55 on the surface of substrate 54. Imaging array 50 includes PMOS transistors such as transistor 52, NMOS transistors such as transistor 51, and photodiodes such as photodiode 53. NMOS transistor 51 is constructed in a P-well 56 whose voltage is set by contact 74. Transistor 51 includes a source 71, gate 72, and drain 69. Similarly, PMOS transistor 52 is constructed in an N-well 57 having a contact 68 used to set the voltage of well 57. The source, gate, and drain of transistor 52 are shown at 66, 67, and 65, respectively.

Photodiode 53 is a pinned photodiode. The anode of the photodiode is epi layer 55 and the cathode is N+ implant 61. A thin P layer 62 is implanted on top of N+ implant. Layer 61, gate electrode 63 and implant 64 form the source, gate, and drain of the transfer gate used to access the charge stored in the photodiode, i.e., gate 22 shown in FIG. 4. In operation, layer 55 is held at ground and implant 61 has a positive potential of about 1 volt. Implant 61 is depleted of electrons, and hence, free electrons generated by light in implant 61 or in the area immediately surrounding implant 61 are accumulated in implant 61. While the stored electrons reduce the potential of implant 61, the potential remains sufficiently above ground to enable the electrons to be removed by connecting implant 61 to a higher potential in implant 64 via the gate transistor. In essence, the electrons are “poured” out of the collection bucket into the parasitic capacitance of a gate of one of the transistors in the pixel.

In a dental application, free electrons can be created by two mechanisms, light from the scintillator or x-ray interactions with the imaging array itself. For example, an x-ray can scatter off of an electron in the silicon and depart sufficient energy to the electron to cause that electron to move through the silicon and scatter off of additional electrons. These electrons will have sufficient energy to move into the conduction band; hence, a single x-ray scattering event can generate a large number of free electrons. The free electrons are generated not only in implant 61, but also in layer 55 and substrate 54. Since layer 51 and substrate 54 are typically more than 100 times thicker than implant 61, most of these electrons are generated outside of implant 61. However, the difference in potential between implant 61 and the other layers causes the electrons to be swept into implant 61, and hence, a single x-ray hit is equivalent to a large number of visible photon generated electrons.

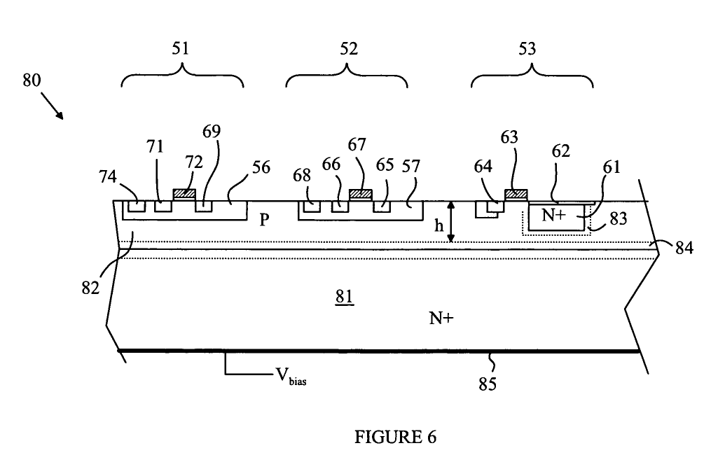

The present invention reduces the number of x-ray generated electrons that reach the N+ implant region of the photodiode by providing a separate depletion region that captures most of the electrons that are generated by the x-rays due to interactions with the electrons in the substrate or areas outside of implant 61. Refer now to FIG. 6, which is a cross-sectional view of a portion of an image sensor according to one embodiment of the present invention. The imaging array is constructed on an N-type substrate 81 by growing a P-type epitaxial layer 82 on substrate 81. The various transistors and photodiodes are then fabricated in layer 82 in a manner similar to that used to generate these structures in imaging array 50 discussed above. The back surface of substrate 81 includes an electrode 85 that is used to bias substrate 81. In operation, this bias voltage results in a second depletion region 84 at the boundary of substrate 81 and layer 82. Electrons that are generated in substrate 81 or in the region near depletion region 84 are swept into the depletion region, and hence, are prevented from being collected by depletion region 83 in photodiode 53. Since substrate 81 is typically more than 100 times the thickness of layer 82, the vast majority of the x-ray generated electrons are generated in substrate 81 and prevented from reaching photodiode 53. Accordingly, the level of x-ray generated background in photodiode 53 is substantially reduced. It should be noted that for the back scattered x-ray photons that impinge from the back side of the sensor, the same principle applies, i.e., the vast majority of the x-ray generated electrons are generated in substrate 81 and prevented from reaching photodiode 53. Hence the back scattering effect is reduced.

The fraction of layer 82 that is occupied by depletion region 84 is a function of the potential applied to substrate 81 through electrode 85. As Vbias is increased, the depletion region grows, i.e., h decreases. Hence, the fraction of the x-ray generated electrons from layer 82 can be reduced by increasing V bias until h is just slightly larger than the height of depletion region 83 in photodiode 53.

It should be noted that if depletion region 84 is increased until it joins depletion region 83, any electrons accumulated in photodiode 53 will be removed. Hence, by increasing Vbias sufficiently, all of the photodiodes in imaging array 80 can be reset. In addition, the photodiodes will remain reset until V_{bias} is decreased to a level that results in depletion region 84 being separated from depletion region 83. It should be noted that this mode of reset can have lower noise than the conventional reset mode used with CMOS imaging arrays. In conventional CMOS imaging arrays, the photodiodes are reset by connecting implant 64 to a reset voltage and then connecting implant 61 to implant 64 using gate 63. After a predetermined time, region 61 is then isolated again and ready to accumulate charge during the image exposure.

If the photodiodes are reset by connecting depletion regions 83 and 84, all of the photodiodes can be reset and then released at the same time. Hence this structure could also provide a global shutter without the use of a mechanical shutter in front of the sensor.

The above-described embodiments of the present invention utilize an N-type substrate and require a contact on the backside of the substrate. Conventional fabrication processes for CMOS imaging arrays start with P-type substrates and the backside contact 95 is not part of the standard CMOS fabrication processes. Hence, it would be advantageous to provide embodiments of the present invention that are more easily accommodated by existing fabrication processes.

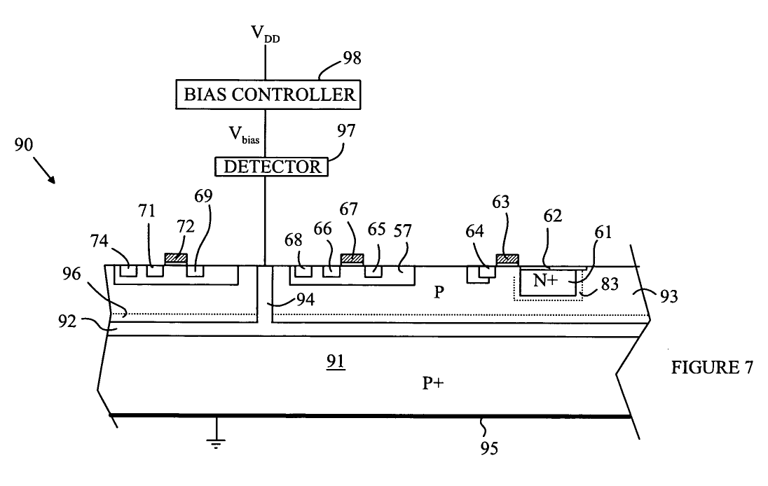

Refer now to FIG. 7, which is a cross-sectional view of another embodiment of an imaging array according to the present invention. Imaging array 90 is constructed on a conventional P+ substrate 91 by growing an epitaxial n-type layer 92 on the substrate prior to growing the p-type layer 93 in which the various wells are formed. A contact 94 is constructed by implanting the p-type layer 93 with a much heavier dose of n implant to provide a conductive connection from the top surface of imaging array 90 to buried n-type layer 92. In practice, this imaging array operates in a manner analogous to that described above with reference to imaging array 80 shown in FIG. 6. By adjusting the potential on buried layer 92, a buried depletion layer 96 is formed that traps electrons that are generated by x-ray interactions in substrate 91 or in epitaxial layer 93 between the layer 92 and the depletion region 83.

As noted above, triggering the imaging array at the beginning of an x-ray exposure presents problems in dental settings in which the x-ray tube is not triggered from the imaging apparatus, as the imaging array must then detect the x-ray pulse and reset the array at the beginning of the x-ray pulse. The buried depletion region of the present invention provides a convenient mechanism for providing the trigger signal as well as the photodiode reset. Consider the case in which Vbias is set such that depletion region 96 is connected to depletion region 83. The imaging array 90 will effectively be held in a reset state. When the x-ray source is turned on, any photo-electrons generated either by light in the scintillator that overlies the imaging array or by x-rays that interact with substrate 91 or layers 92 and 93 are collected by layer 92 and discharged through contact 94. Hence, the beginning of the x-ray pulse is characterized by a current pulse on the V_{bias} conductor. In one embodiment of the present invention, this current pulse is detected by a detector 97 and used by a bias controller 98 as a trigger for commencing the image acquisition. The image acquisition will commence when V_{bias} is reduced to the point that depletion regions 83 and 96 separate from one another.

During the time in which depletion regions 83 and 96 are joined, the entire imaging array including the substrate becomes a single photodiode. Hence, the commencement of the x-ray pulse can be detected with high precision because of the large signal generated on the V_{bias} line. It should also be noted that this mechanism for detecting the beginning of the x-ray pulse does not require any additional scintillators or photodiodes and does not require that the imaging array be periodically readout and reset. It should be noted that this method for detecting the commencement of the x-ray exposure could also be practiced with the embodiments shown in FIG. 6 by measuring the current passing through electrode 85 on the backside of substrate 81.

It should be noted that the present invention is also well suited for operation in environments that have a significant background radiation from high-energy charged particles. Such particles also generate electron-hole pairs in the substrate.

Various modifications to the present invention will become apparent to those skilled in the art from the foregoing description and accompanying drawings. Accordingly, the present invention is to be limited solely by the scope of the following claims.

What is claimed is:

1. An imaging array comprising:
a semiconductor substrate having an epitaxial layer of semiconductor material deposited on a first surface thereof;
a plurality of photodiodes formed in a top surface of said epitaxial layer; and
a depletion layer underlying said photodiodes and disposed between said epitaxial layer and said semiconductor substrate, said depletion layer being connected to a power rail for removing electrons collected in said depletion layer, said depletion layer collecting electrons generated in said substrate.

2. The imaging array of claim 1 wherein said epitaxial layer is characterized by a first semiconductor type and wherein said depletion layer comprises a boundary between said epitaxial layer and a depletion generating layer of semiconductor material having the opposite semiconductor type, said depletion generating layer having a contact for maintaining said depletion generating layer at a bias potential.

3. The imaging array of claim 2 wherein said depletion generating layer comprises said substrate and said contact comprises an electrode on a surface of said substrate different from said first surface.

4. The imaging array of claim 3 wherein said substrate is an n-type semiconductor.

5. The imaging array of claim 2 wherein said depletion generating layer comprises a buried layer between said semiconductor substrate and said epitaxial layer.

6. The imaging array of claim 5 wherein said contact comprises an implant region that is accessed from said top surface of said epitaxial layer.

7. The imaging array of claim 5 wherein said substrate comprises a p-type semiconductor.

8. The imaging array of claim 2 further comprising a detector that detects a current flowing through said contact.

9. The imaging array of claim 2 further comprising a circuit for varying a variable bias potential on said depletion generating layer.

10. The imaging array of claim 9 wherein said depletion layer has a dimension that varies with said variable bias potential, said depletion layer extending into a depletion region of said photodiodes at a first bias potential and being separated from said depletion region of said photodiodes at a second bias potential.

11. The imaging array of claim 1 further comprising a layer of scintillation material overlying said photodiodes, said scintillation material converting x-rays to light in a spectral region that is detectable by said photodiodes.

12. A method for acquiring an image comprising:
providing an imaging array, said imaging array comprising:
a semiconductor substrate having an epitaxial layer of semiconductor material deposited on a first surface thereof;
a plurality of photodiodes formed in a top surface of said epitaxial layer; and
a depletion layer underlying said photodiodes and disposed between said epitaxial layer and said semiconductor substrate; and
biasing said depletion layer at a first potential that causes said depletion layer to collect electrons generated in said substrate.

13. The method of claim 12 further comprising biasing said depletion layer at a second potential that causes said depletion layer to collect electrons generated in said photodiodes prior to biasing said depletion layer to said first potential.

14. The method of claim 12 further comprising measuring a current flowing through said depletion region.

15. The method of claim 14 wherein said depletion region is switched from said second potential to said first potential in response to said current exceeding a predetermined threshold.
